(19) United States
(12) Patent Application Publication
(10) Pub. No.: US 2008/0258288 A1
(43) Pub. Date: Oct. 23, 2008

(54) Semiconductor device stack package, electronic apparatus including the same, and method of manufacturing the same

(75) Inventors: Jin-woo Park, Chungcheongnam-do (KR); Cha-je Jo, Gyeonggi-do (KR); Eun-chul Ahn, Gyeonggi-do (KR); Tae-joo Hwang, Gyeonggi-do (KR); Hae-jung Yu, Gyeonggi-do (KR); Chan Park, Gyeonggi-do (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/148,404

(22) Filed: Apr. 18, 2008

(30) Foreign Application Priority Data
Apr. 19, 2007 (KR) 10-2007-0038326

(51) Int. Cl. H01L 23/48; H01L 21/50

(52) U.S. Cl. 257/686; 438/109; 257/E23.01; 257/E21.499

(57) ABSTRACT

In a semiconductor device stack package and a method of forming the same, the package comprises: a substrate; a plurality of lower chips stacked on the substrate and having an active surface oriented in a direction toward the substrate; and at least one upper chip disposed on the lower chips and connected to the substrate via a bump disposed between the lower chips. As no wire loops are formed, there is no increase in the height of the stack package, and the electrical path is shortened, thereby improving the electric performance of the stack package. Also, the semiconductor device stack package has a flip chip structure, and thus a plurality of semiconductor chips can be stacked in various manners.

### CROSS-REFERENCE TO RELATED PATENT APPLICATION

This application claims the benefit of Korean Patent Application No. 10-2007-0038326, filed on Apr. 19, 2007, in the Korean Intellectual Property Office, the disclosure of which is incorporated herein in its entirety by reference.

### BACKGROUND OF THE INVENTION

1. Field of the Invention

Embodiments of the present invention relate to a semiconductor device stack package, an electronic apparatus including the same, and a manufacturing method of the semiconductor device stack package, and more particularly, to a stack package in which an active surface of an upper chip is oriented toward a substrate and the upper chip is connected via a bump-type interconnect to the substrate, an electronic apparatus including the stack package, and a manufacturing method of the semiconductor device stack package.

2. Description of the Related Art

In general, a plurality of semiconductor chips are commonly formed on a semiconductor substrate using a plurality of semiconductor processes, and a semiconductor device package is formed by performing a packaging process on the semiconductor substrate to mount the semiconductor chips to the semiconductor substrate. In order to increase the storage capacity of the semiconductor device package, semiconductor device stack packages in which a plurality of semiconductor chips are stacked have been under development. The semiconductor device stack package typically includes a substrate, semiconductor chips, an adhesive, solder balls, a wire loop, and an epoxy molding compound (EMC). Recently, a multi-chip package has been widely used as a semiconductor device stack package in order to obtain a high-capacity, multi-functional high-response-speed semiconductor device stack package.

The semiconductor chips can be electrically connected to the substrate using any of a number of techniques, including a wire bonding method, a flip chip method, or a through-hole via method. However, in the flip chip method, it is difficult to connect the upper chips of a stack structure formed of two or more layers. In the wire bonding method, long wires are used to connect the stacked semiconductor chips. Long wires can be the source of electrical short circuits as a result of the wire sweeping phenomenon that can occur during a molding process for thermal protection and can hinder height reduction of the stack package. The through hole via method requires a complicated fabrication process and can be electrically instable.

When stacking a stack package using the wire bonding method and the flip chip method in combination, the height of the stack package can be reduced by mounting a lower device on a substrate using flip chip interconnection; however, the upper device is still bonded using the wire bonding approach. That is, although the wire bonding and flip chip methods are combined in a single package, the package still suffers from the limitation of the wire length of wire loops being too long, and thus the electrical performance and manufacturing reliability of the package can be hindered, and, at the same time, it can be difficult to reduce the overall package height. Accordingly, realization of high capacity and high response speed and reduction of the package size continue to be essential parameters for a semiconductor device stack package.

FIGS. 1A and 1B are cross-sectional views of an example of a conventional semiconductor stack package.

Referring to FIGS. 1A and 1B, a conventional semiconductor stack package includes a substrate 10, solder balls 11, a semiconductor chip 12, wire loops 13, an adhesive 14, bumps 15, and an epoxy molding compound (EMC) 16. A lower semiconductor device has a flip chip structure in which an active surface of the device is oriented toward the substrate 10 and is connected to the substrate via the bumps 15, and an upper semiconductor device has an active surface oriented in a direction opposite the substrate 10 and the wire loop 13 is connected to the substrate 10 via an edge pad.

In detail, since the upper semiconductor device is of a wire bonding type, the electrical path is relatively long and thus the electrical performance of the semiconductor device can be limited by the long length of the bonding wires. Also, the package height is relatively large due to the wire bonding and thus the form factor size is thereby limited. Also, when the wire loops 13 are encapsulated using the EMC, the wire sweeping phenomenon may result. When the upper semiconductor device is in an edge pad structure, as shown in FIG. 1A, the length of the wire loop 13 is shorter than the length of the wire loops of a center pad structure, as shown in FIG. 1B, and thus the problem may be less severe, but in the case of a center pad structure, the problem becomes serious.

FIG. 2 is a cross-sectional view of another example of a conventional semiconductor stack package.

Referring to FIG. 2, the conventional semiconductor stack package is of a board on chip (BOC) type and includes a substrate 10, solder balls 11, a semiconductor chip 12, wire loops 13, an adhesive, and an EMC 16. The semiconductor chip 12 has a flip chip structure in which an active surface is oriented toward the substrate 10 and is electrically connected to the substrate 10 by wire bonding through an opening, or slit, that is formed in the substrate 10. Since the stack package is not a wire bonding structure oriented in an upward direction, the height of the stack package can be reduced. However, a slit must be formed in the substrate 10, and exfoliation may be generated due to the weak adhesive force between the EMC and the semiconductor chip 12. In addition, wire sweeping due to the EMC flow pressure during a molding process can still occur, or the semiconductor chips can be damaged. Also, the semiconductor chip 12 is still of a wire bonding type and is connected to the substrate, and thus the electrical path is relatively long, which can result in poor electrical performance of the semiconductor stack package.

FIG. 3 is a cross-sectional view of another example of a conventional semiconductor device stack package having a through hole via structure.

Referring to FIG. 3, via holes 17 vertically passing through a semiconductor chip 12 are electrically connected to each other and are bonded to a substrate 10. The via holes 17 are formed by laser drilling, insulating layer coating, seed metal layer coating, and electrolytic/non-electrolytic plating processes that are performed sequentially. However, these processes are relatively expensive to perform and the resulting interconnection reliability between the semiconductor chips can be low. Also, in some cases, the holes will not be completely filled and thus cavities can be formed, which can cause instable electrical connection.

As such, a semiconductor device stack package including a wire bonding structure has several disadvantages in terms of electrical and physical properties. A through hole via structure has disadvantages with respect to the manufacturing cost and electrical connection.

### SUMMARY OF THE INVENTION

Embodiments of the present invention provide a semiconductor device stack package and electronic apparatus including the same, wherein the semiconductor device stack package has a flip chip structure.

Embodiments of the present invention also provide a method of manufacturing the semiconductor device stack package.

In one aspect, a semiconductor device stack package comprises: a substrate; a plurality of lower chips stacked on the substrate and having an active surface oriented in a direction toward the substrate; and at least one upper chip disposed on the lower chips and connected to the substrate via a bump disposed between the lower chips.

In one embodiment, the lower chips are formed to be electrically connected to the substrate via a bump disposed between the lower chips and the substrate.

In another embodiment, the upper chip has a central pad that is centrally positioned.

In another embodiment, the substrate further comprises solder balls attached to a lower surface of the substrate.

In another embodiment, the upper chip comprises a plurality of the upper chips.

In another embodiment, the semiconductor device stack package further comprises an uppermost chip stacked on the upper chip and electrically connected to the substrate via a bump disposed between the lower chips and between the upper chips.

In another embodiment, the lower chips are disposed on both sides of the central pad.

In another embodiment, the lower chips are disposed on both sides of the central pad, and the lower chips disposed at one side of the central pad are separated into several parts.

In another embodiment, the lower chips are disposed on both sides of the central pad, and the lower chips disposed at both sides of the center pad are separated into several parts.

In another embodiment, the upper chip includes multiple pads arranged in a cross-shaped configuration.

In another embodiment, the semiconductor device stack package further comprises a heat spreader on the at least one upper chip.

In another embodiment, the height of the bump connected to the at least one upper chip and the substrate is longer than the height of the bumps connected to the lower chips and the substrate.

In another aspect, an electronic apparatus comprises: a substrate; a plurality of lower chips stacked on the substrate and having an active surface oriented in a direction toward the substrate; and at least one upper chip that is electrically connected to the substrate via a bump disposed between the lower chips.

In another aspect, a method of manufacturing a semiconductor device stack package comprises: providing a substrate; providing a plurality of lower chips on the substrate such that an active surface of the lower chips is oriented in a direction toward the substrate and such that the lower chips and the substrate are electrically connected via a bump; providing an upper chip on the lower chips such that an active surface of the upper chips is oriented toward the substrate; and providing the upper chip to be electrically connected to the substrate via a bump disposed between the lower chips.

In one embodiment, providing the upper chip to be electrically connected to the substrate comprises: exposing a pad formed on the active surface of the upper chip and coating the exposed portion using an adhesive; connecting the bump to the exposed pad of the active surface; and electrically connecting the upper chip to the substrate by providing the bump between the lower chips.

In another embodiment, the method further comprises, after electrically connecting the upper chip to the substrate, attaching a heat spreader on an upper surface of the upper chip.

In another embodiment, the method further comprises, after attaching the heat spreader, molding the package using a sealing member.

In another embodiment, the method further comprises, after molding the package, attaching solder balls to an exposed surface of the substrate.

In another embodiment, the method further comprises, after attaching the heat spreader, attaching solder balls to an exposed surface of the substrate.

In another embodiment, the method further comprises, after attaching the solder balls, molding the package using a sealing member.

In the semiconductor device stack package according to the embodiments of the present invention, since no wire loops are included, the height of the semiconductor device stack package is not increased, and the electrical performance of the package is improved by reducing the length of the electrical path. Also, the stack package is formed of a flip chip configuration and a plurality of chips can be stacked, and the stack package can be used in various manners. Also, a heat spreader can be attached to the semiconductor device stack package to efficiently radiate heat.

The electric performance of the semiconductor device stack package is improved by reducing the length of the electrical path, and as no wire bonding is used, wire sweeping which is possibly generated during encapsulation is prevented and the stack height of the semiconductor device stack package can be reduced. The stack package according to the embodiments of the present invention further includes a heat spreader on a back side of an uppermost chip, thereby efficiently dissipating heat generated within the semiconductor device stack package.

### BRIEF DESCRIPTION OF THE DRAWINGS

The above and other features and advantages of the embodiments of the present invention will become more apparent by describing in detail exemplary embodiments thereof with reference to the attached drawings in which:

FIG. 1A is a cross-sectional view of an example of a conventional semiconductor device stack package having an edge pad structure;

FIG. 1B is a cross-sectional view of an example of a conventional semiconductor device stack package having a center pad structure

FIG. 2 is a cross-sectional view of another example of a conventional semiconductor device stack package;

FIG. 3 is a cross-sectional view of an example of a conventional semiconductor device stack package having a through hole via structure;

FIG. 4 is a cross-sectional view of a semiconductor device stack package according to an embodiment of the present invention;

FIGS. 5A and 5B are plan views illustrating the semiconductor device stack package of FIG. 4;

FIG. 6 is a plan view of a semiconductor device stack package according to another embodiment of the present invention;

FIG. 7 is a plan view of a semiconductor device stack package according to another embodiment of the present invention;

FIG. 8 is a plan view of a semiconductor device stack package according to another embodiment of the present invention;

FIG. 9 is a cross-sectional view of a semiconductor device stack package according to another embodiment of the present invention;

FIG. 10 is a plan view of a semiconductor device stack package according to another embodiment of the present invention;

FIG. 11 is a cross-sectional view of a semiconductor device stack package according to another embodiment of the present invention;

FIGS. 12 and 13 are flow diagrams of a method of manufacturing a semiconductor device stack package according to the present invention; and

FIGS. 14A and 14B are perspective views illustrating electronic apparatuses including the semiconductor device stack package according to the present invention.

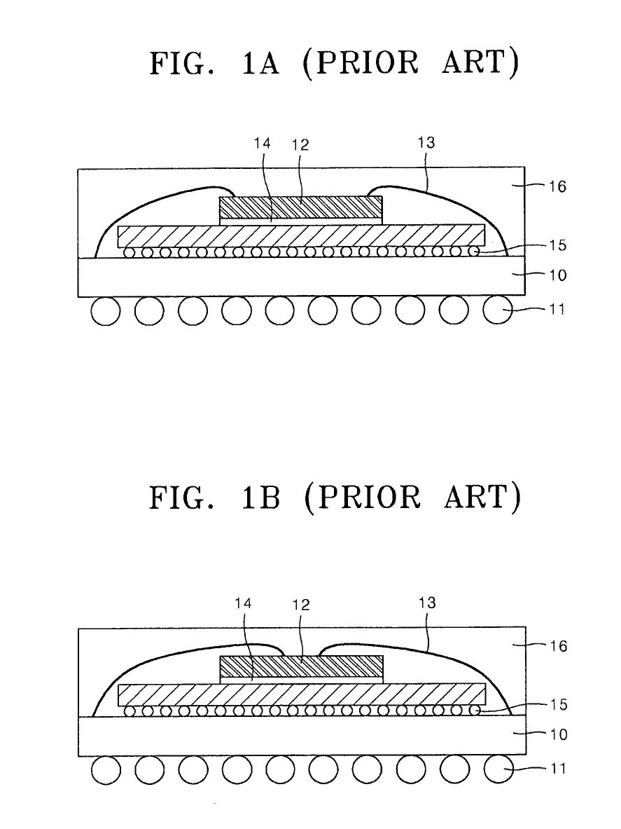

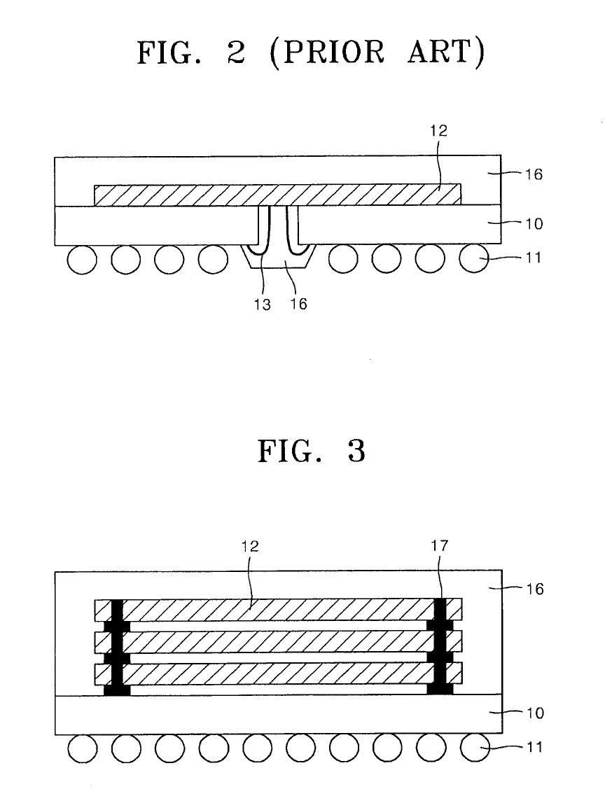

### DETAILED DESCRIPTION OF EMBODIMENTS

Embodiments of the present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

It will be understood that, although the terms first, second, etc. are used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.). When an element is referred to herein as being “over” another element, it can be over or under the other element, and either directly coupled to the other element, or intervening elements may be present, or the elements may be spaced apart by a void or gap.

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

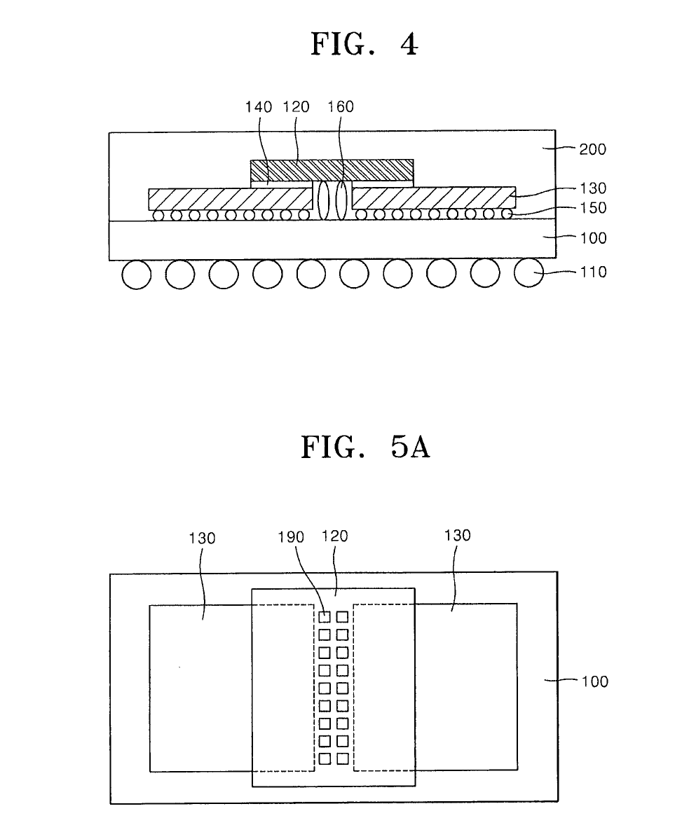

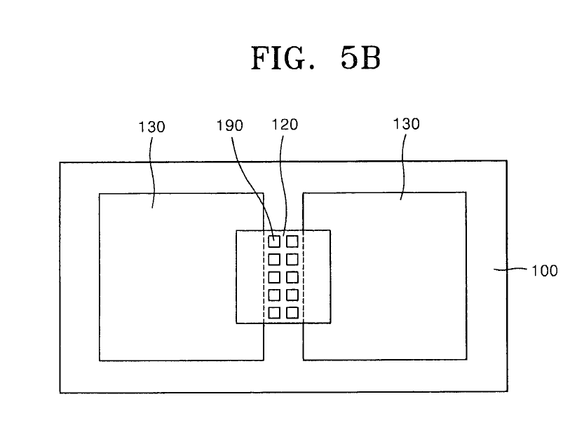

FIG. 4 is a cross-sectional view of a stack package according to an embodiment of the present invention (hereinafter referred to as ‘first package’). FIGS. 5A and 5B are plan views illustrating the stack package of FIG. 4.

Referring to FIGS. 4, 5A, and 5B, the first package includes a substrate 100, solder balls 110, an upper chip 120, a plurality of lower chips 130, an adhesive 140, and bumps 150 and 160. The substrate 100 may be a printed circuit board (PCB).

The substrate 100 includes a plurality of solder balls 110. The lower chips 130 are formed on the substrate 100 in a flip chip structure having an active surface oriented in a direction toward the substrate 100 and are electrically connected to each other via the substrate 100 and the bumps 150. The lower chips 130 are mounted at regular intervals on the substrate 100, and a pad or multiple pads of the upper chip 120 are disposed between the lower chips 130.

A pad 190 of the upper chip 120 is electrically connected to the substrate 100 via the bump 160, and the length, or height, of the bump 160 is equal to the total of the height of the lower chip 130 and the height of the bump 150 which electrically connects the lower chips 130 and the substrate 100. The lower chips 130 and the upper chip 120 may have a homogeneous or heterogeneous structure. The size in width, length, or height of the upper chip 120 may be different than or the same as the size in width, length, or height of the lower chip 130. For example, the upper chip 120 in the example of FIG. 5A is greater in width than the lower chips 130, while the upper chip 120 in the example of FIG. 5B is less in width than the lower chips 130. The pad 190 of the upper chip 120 may be a centrally located pad or multiple pads formed in one or more rows or columns. The pad 190 is electrically connected to the substrate 100 via bumps 160, and can provide the function, for example, of an input/output signal pad and a power/ground pad.

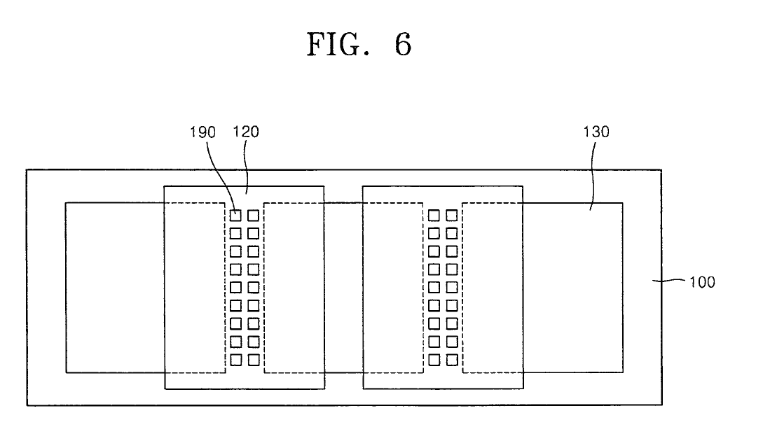

FIGS. 6 through 8 are plan views of stack packages according to other embodiments of the present invention (hereinafter referred to as ‘second package’).

Referring to FIGS. 6 through 8, the second package includes a substrate 100, a plurality of upper chips 120, a plurality of lower chips 130, and a pad 190. The substrate 100 may include a PCB. The plurality of lower chips 130 and the plurality of upper chips 120 may have a homogeneous or heterogeneous structure. The pad 190 of the upper chip 120 may be a centrally located pad, and multiple pads may be formed in one or more rows or columns. Since the plurality of upper chips 120 are stacked on the plurality of lower chips 130, a high-capacity stack package can be realized.

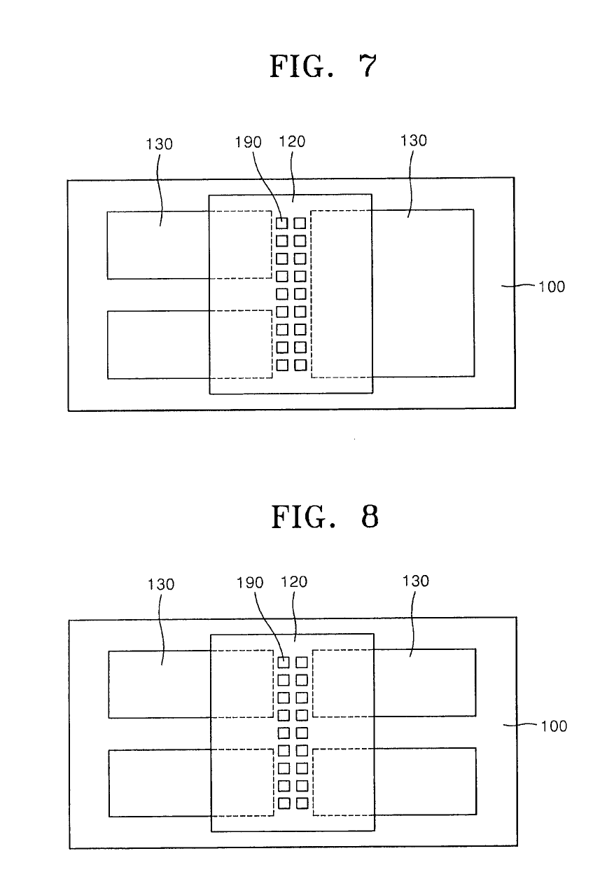

The second package is different from the first package in that the lower chips 130 formed on the substrate 100 are arranged differently than those of the first package. In detail, as illustrated in FIG. 6, the lower chips 130 may be formed on both sides of the pad 190, centered relative to the pad 190 and extending repeatedly in one direction. In another example as illustrated in FIG. 7, one of the lower chips 130 that are formed on both sides of the pad 190 and centered relative to the pad 190 can be separated into several components (two parts in FIG. 7) or as illustrated in FIG. 8, the lower chips 130 formed on both sides of the pad 190 and centered relative to the pad 190 may be separated into several components (each into two parts in FIG. 8).

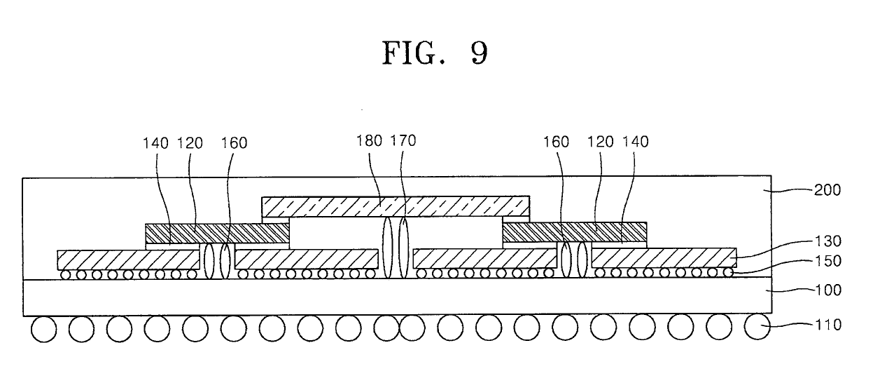

FIG. 9 is a cross-sectional view of a stack package according to another embodiment of the present invention (hereinafter referred to as ‘third package’).

Referring to FIG. 9, the third package includes a substrate 100, solder balls 110, a plurality of upper chips 120, a plurality of lower chips 130, an adhesive 140, bumps 150, 160, and 170, an uppermost chip 180, and a sealing member 200. The substrate 100 may include a PCB. The lower chips 130, the upper chips 120, and the uppermost chip 180 may have a homogeneous or heterogeneous structure. The upper chips 120 and the uppermost chip 180 may be a centrally located pad, and a plurality of the pads can be arranged in one or more rows or columns.

As described above, the lower chips 130 and the substrate 100 are connected via the bumps 150, and the upper chips 120 and the substrate 100 are connected via the pads 190 and the bumps 160. The third package is different from the first and second packages in that the uppermost chip 180 is electrically connected to the substrate 100 via the additional bumps 170 that are coupled to the centrally located pads 190 of the uppermost chip 180. The height of the additional bumps 170 is substantially equal to the combined heights of the bumps 150, the lower chips 130, the adhesive layers 140 and the upper chips 120. The third package shown in FIG. 9 has high capacity as the uppermost chip 180 is stacked on the upper chips 120.

FIG. 10 is a plan view of a stack package according to another embodiment of the present invention (hereinafter referred to as ‘fourth package’).

Referring to FIG. 10, the fourth package includes a substrate 100, an upper chip 120, a plurality of lower chips 130, and a pad 190. The substrate 100 may, for example, comprise a PCB. The upper chip 120 and the lower chips 130 may have a homogeneous or heterogeneous structure. The pad 190 may comprise a plurality of pads arranged in a cross shape configuration as shown and may be arranged in one or more rows or columns. The configuration of the fourth package can provide for additional input/output signal pads and power/ground pads for a high capacity chip stack by increasing the number of pads 190 as needed. Also, since the upper chip 120 is stacked on the lower chips 130, a high capacity stack package can be realized.

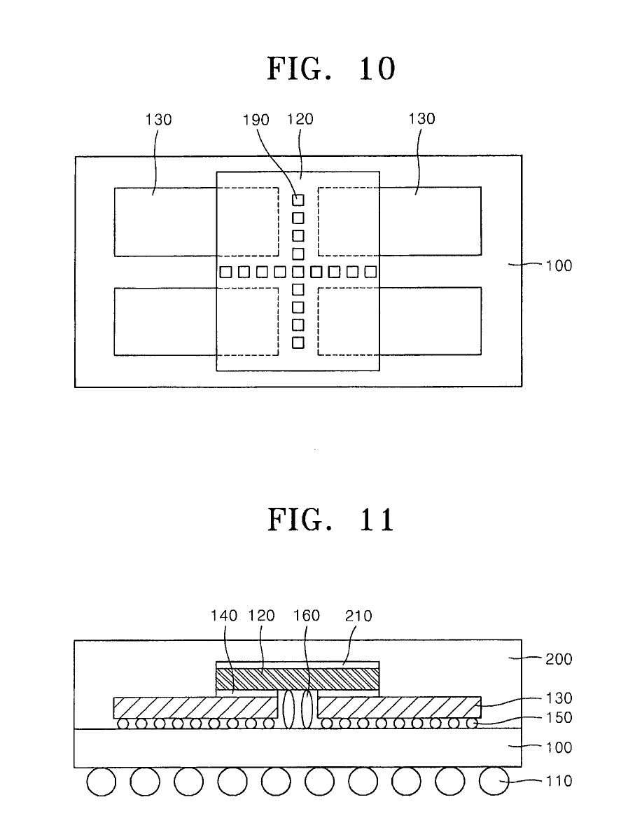

FIG. 11 is a plan view of a stack package according to another embodiment of the present invention (hereinafter referred to as ‘fifth package’).

Referring to FIG. 11, the fifth package includes a substrate 100, solder balls 110, an upper chip 120, a plurality of lower chips 130, an adhesive 140, bumps 150 and 160, and a heat spreader 210 on a top surface of the upper chip 120.

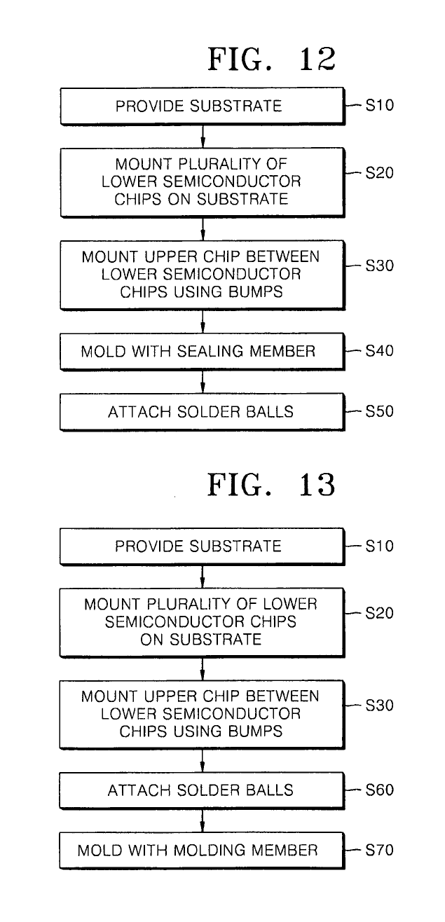

FIGS. 12 and 13 are flow diagrams of a method of manufacturing a stack package according to the present invention. In various embodiments, the second through fifth packages described above can be manufactured according to this method.

Referring to FIG. 12, first, a substrate is provided (operation S10). Then a plurality of lower chips are formed on the substrate such that an active surface of the lower chips is oriented toward the substrate and the lower chips are electrically connected to the substrate via bumps (S20). An upper chip is formed on the lower chip such that an active surface of the upper chip is oriented toward the substrate. The upper chip is formed between the lower chips to be electrically connected to the substrate via bumps of the lower chip. After molding the stack package with a sealing member (S40), solder balls are attached to the stack package (S50). Alternatively, as shown in FIG. 13, first solder balls may be attached to the stack package (S60) and then the stack package is molded using a sealing member (S70) to manufacture a semiconductor device stack package.

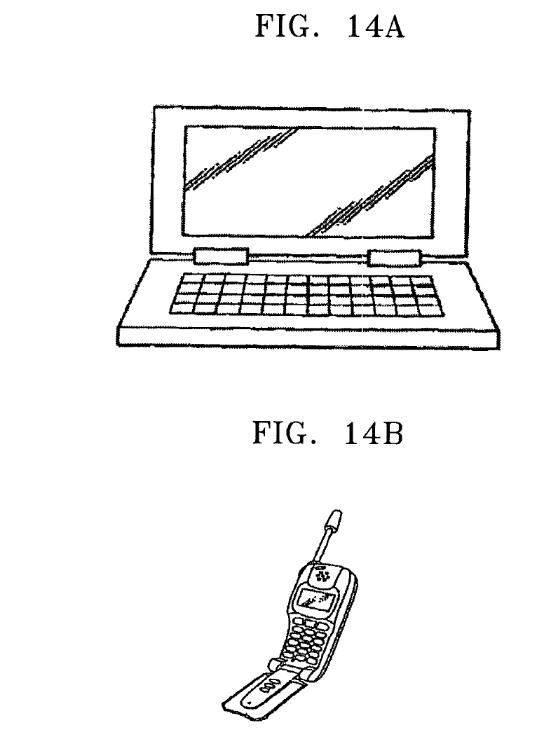

FIGS. 14A and 14B are perspective views illustrating electronic apparatuses including the stack package according to the present invention. These electronic apparatus are examples, and the stack package according to the present invention can be used in conjunction with various kinds of electronic apparatuses within the scope of the present invention. Examples of such electronic apparatuses include a computer as illustrated in FIG. 14A and a mobile phone as illustrated in FIG. 14B.

As described above, according to the embodiments of the present invention, since no wire loops are formed, there is no need for an increase in the height of the stack package, and the electrical path is shortened, thereby improving the electric performance of the stack package.

Also, the stack package according to the embodiments of the present invention has a flip chip structure, and thus a plurality of semiconductor chips can be stacked in various manners. In addition, the stack package according to the present invention may further include a heat spreader to readily dissipate heat.

While embodiments of the present invention have been particularly shown and described with reference to exemplary embodiments thereof, it will be understood by those of ordinary skill in the art that various changes in form and details may be made herein without departing from the spirit and scope of the present invention as defined by the following claims.

What is claimed is:

1. A semiconductor device stack package comprising:
a substrate;
a plurality of lower chips stacked on the substrate and having an active surface oriented in a direction toward the substrate; and
at least one upper chip disposed on the lower chips and connected to the substrate via a bump disposed between the lower chips.

2. The semiconductor device stack package of claim 1, wherein the lower chips are formed to be electrically connected to the substrate via a bump disposed between the lower chips and the substrate.

3. The semiconductor device stack package of claim 1, wherein the upper chip has a central pad that is centrally positioned.

4. The semiconductor device stack package of claim 1, wherein the substrate further comprises solder balls attached to a lower surface of the substrate.

5. The semiconductor device stack package of claim 1, wherein the upper chip comprises a plurality of the upper chips.

6. The semiconductor device stack package of claim 5, further comprising an uppermost chip stacked on the upper chip and electrically connected to the substrate via a bump disposed between the lower chips and between the upper chips.

7. The semiconductor device stack package of claim 3, wherein the lower chips are disposed on both sides of the central pad.

8. The semiconductor device stack package of claim 3, wherein the lower chips are disposed on both sides of the central pad, and the lower chips disposed at one side of the central pad are separated into several parts.

9. The semiconductor device stack package of claim 3, wherein the lower chips are disposed on both sides of the central pad, and the lower chips disposed at both sides of the center pad are separated into several parts.

10. The semiconductor device stack package of claim 1, wherein the upper chip includes multiple pads arranged in a cross-shaped configuration.

11. The semiconductor device stack package of claim 1, further comprising a heat spreader on the at least one upper chip.

12. The semiconductor device stack package of claim 1, wherein the height of the bump connected to the at least one upper chip and the substrate is longer than the height of the bumps connected to the lower chips and the substrate.

13. An electronic apparatus comprising:
a substrate;
a plurality of lower chips stacked on the substrate and having an active surface oriented in a direction toward the substrate; and
at least one upper chip that is electrically connected to the substrate via a bump disposed between the lower chips.

14. A method of manufacturing a semiconductor device stack package, the method comprising:
providing a substrate;
providing a plurality of lower chips on the substrate such that an active surface of the lower chips is oriented in a direction toward the substrate and such that the lower chips and the substrate are electrically connected via a bump;
providing an upper chip on the lower chips such that an active surface of the upper chips is oriented toward the substrate; and
providing the upper chip to be electrically connected to the substrate via a bump disposed between the lower chips.

15. The method of claim 14, wherein providing the upper chip to be electrically connected to the substrate comprises:
exposing a pad formed on the active surface of the upper chip and coating the exposed portion using an adhesive;
connecting the bump to the exposed pad of the active surface; and
electrically connecting the upper chip to the substrate by providing the bump between the lower chips.

16. The method of claim 15, further comprising, after electrically connecting the upper chip to the substrate, attaching a heat spreader on an upper surface of the upper chip.

17. The method of claim 16, further comprising, after attaching the heat spreader, molding the package using a sealing member.

18. The method of claim 17, further comprising, after molding the package, attaching solder balls to an exposed surface of the substrate.

19. The method of claim 16, further comprising, after attaching the heat-spreader, attaching solder balls to an exposed surface of the substrate.

20. The method of claim 19, further comprising, after attaching the solder balls, molding the package using a sealing member.
